(19) United States
(12) Patent Application Publication
(10) Pub. No.: US 2026/0314159 A1
(43) Pub. Date: Oct. 8, 2026

(54) NANOPARTICLES, LIGHT-EMITTING ELEMENT, AND DISPLAY DEVICE

(71) Applicant: Sharp Display Technology Corporation, Kameyama City, Mie (JP)

(72) Inventors: Hisayuki UTSUMI, Kameyama City (JP); Takayuki NAKA, Sakai City (JP); Makoto NOZOE, Kameyama City (JP)

(21) Appl. No.: 19/157,710

(22) PCT Filed: Feb. 27, 2023
(86) PCT No.: PCT/JP2023/006972

§ 371 Date: Aug. 19, 2025

(51) Int. Cl. H10K 50/115; H10K 50/17

(52) U.S. Cl. CPC H10K 50/115; H10K 50/17

(57) ABSTRACT

Nanoparticles to be used for a functional layer of a light-emitting element, include nickel oxide, the nanoparticles having an infrared absorption spectrum obtained by infrared spectroscopy, and the infrared absorption spectrum having an absorption peak at a wave number corresponding to nitrate ions.

### TECHNICAL FIELD

The present disclosure relates to nanoparticles, a light-emitting element a functional layer of which contains the nanoparticles, and a display device including the light-emitting element.

### BACKGROUND ART

Patent Document 1 discloses an example in which a functional layer such as a charge transport layer of a light-emitting element contains nanoparticles as a material.

### CITATION LIST

### Patent Literature

[Patent Document 1] Japanese Unexamined Patent Application Publication No. 2019-522367

### SUMMARY

### Technical Problem

In depositing a functional layer containing nanoparticles as a material, a possible technique is to apply a solution in which the nanoparticles are dispersed. In this case, in order to improve characteristics of the deposited functional layer, the technique is required to ensure that the nanoparticles disperse in the solution so that the nanoparticles are less likely to agglomerate together.

### Solution to Problem

Nanoparticles according to an aspect of the present disclosure are nanoparticles to be used for a functional layer of a light-emitting element. The nanoparticles include nickel oxide. The nanoparticles have an infrared absorption spectrum obtained by infrared spectroscopy, and the infrared absorption spectrum has an absorption peak at a wave number corresponding to nitrate ions.

A light-emitting element according to another aspect of the present disclosure includes: an anode; a cathode; and functional layers positioned between the anode and the cathode and including at least a light-emitting layer. At least one of the functional layers contains: nickel oxide; and nanoparticles having an infrared absorption spectrum obtained by infrared spectroscopy. The infrared absorption spectrum has an absorption peak at a wave number corresponding to nitrate ions.

### Advantageous Effect of Disclosure

The present disclosure provides nanoparticles less likely to agglomerate together in a solution and a light-emitting element a functional layer of which contains the nanoparticles.

### BRIEF DESCRIPTION OF DRAWINGS

FIG. 1 illustrates a schematic sectional side view of a display device according to an embodiment.

FIG. 2 illustrates a schematic plan view of the display device according to the embodiment.

### DESCRIPTION OF EMBODIMENT

### Embodiment

### Display Device

Described below is an embodiment of the present disclosure with reference to the drawings. Note that, throughout the drawings, like reference signs designate identical constituent features. Such constituent features will not be elaborated upon.

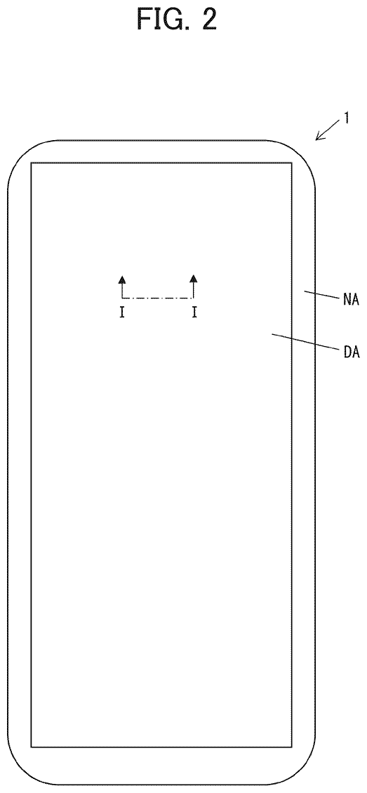

FIG. 2 is a schematic plan view of a display device 1 according to this embodiment. The display device 1 is a device to be used for a display of such an appliance as, for example, a TV or a smartphone. The display device 1 includes: a display unit DA; and a picture-frame unit NA formed around an outer periphery of the display unit DA. The display device 1 controls light emitted from each of a plurality of light-emitting elements formed in the display unit DA. Hence, the display device 1 displays an image on the display unit DA. The light-emitting elements will be described later. The picture-frame unit NA may have such a unit as a driver formed to drive each of the plurality of light-emitting elements in the display unit DA.

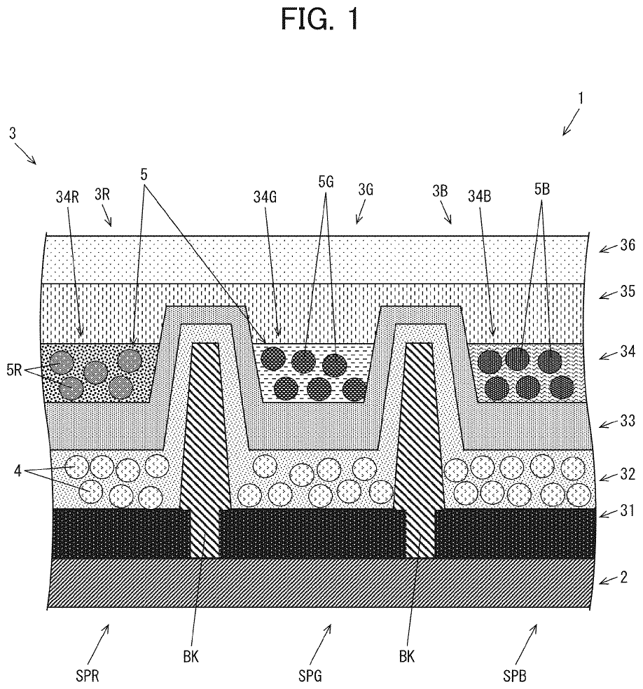

Described below in more detail with reference to FIG. 1 will be a structure of the display unit DA of the display device 1 according to this embodiment. FIG. 1 is a schematic cross-sectional view of the display device 1 according to this embodiment, taken along line I-I in FIG. 2. In particular, FIG. 1 is a view showing a cross-section across a red subpixel SPR, a green subpixel SPG, and a blue subpixel SPB in a plan view of the display device 1 according to this embodiment. The red, green, and blue subpixels SPR, SPG, and SPB will be described later. In the present disclosure, the direction from a substrate 2 toward a cathode 36 of the display device 1 is referred to as “upwards”, and the direction opposite to “upwards” is referred to as “downwards”. The substrate 2 and the cathode 36 will be described later.

### Substrate

As illustrated in FIG. 1, the display device 1 includes the substrate 2. The substrate 2 is positioned to overlap with the display unit DA and the picture-frame unit NA in a plan view of the display device 1. In other words, the substrate 2 is formed over the display unit DA and the picture-frame unit NA. The substrate 2 may have an upper surface substantially in parallel with a display surface of the display device 1. In other words, the substrate 2 may be substantially the same in plan view as the display device 1. The substrate 2 may be, for example, a rigid substrate such as a glass substrate. Alternatively, the substrate 2 may be a flexible substrate including a film substrate containing a PET film. In the latter case, the display device 1 may be a flexible device.

The display device 1 includes the red subpixel SPR, the green subpixel SPG, and the blue subpixel SPB, all of which are positioned to overlap with the display unit DA in a plan view of the substrate 2. The red subpixel SPR includes a red light-emitting element 3R, the green subpixel SPG includes a green light-emitting element 3G, and the blue subpixel SPB includes a blue light-emitting element 3B. The red, green, and blue light-emitting elements 3R, 3G, and 3B will be described later. The substrate 2 may have pixel circuits (not shown) each including, for example, a transistor connected to an anode 31 of a corresponding one of the light-emitting elements described above. The anode 31 will be described later. Furthermore, the substrate 2 may have a driver (not shown) positioned to overlap in a plan view with the picture-frame unit NA. The driver drives each of the pixel circuits.

The substrate 2 may be produced to include such circuits as transistors and drivers formed on the glass substrate. Alternatively, the glass substrate may be removed and replaced with, for example, a film substrate. Hence, with the film substrate attached, the substrate 2 may be a flexible substrate. Furthermore, at a step of producing the display device 1, a plurality of light-emitting elements 3 may be formed on a glass substrate in a large size. After that, the glass substrate may be cut out into a plurality of the substrates 2 so that a plurality of the display devices 1 may be produced.

### Light-Emitting Element: Outline

The display device 1 includes a light-emitting element 3. The light-emitting elements 3 includes the anode 31 and the cathode 36 provided on the substrate 2 in the stated order. Furthermore, the light-emitting element 3 includes: a hole injection layer 32; a hole transport layer 33; a light-emitting layer 34; and an electron transport layer 35, all of which are arranged in the stated order from toward the substrate 2 to serve as functional layers positioned between the anode 31 and the cathode 36. Note that the light-emitting element 3 in this embodiment shall not be limited to such a configuration. The light-emitting element 3 may include: a cathode; an electron transport layer; a light-emitting layer, a hole transport layer; a hole injection layer; and an anode, all of which are arranged in the stated order from toward the substrate 2. Moreover, the light-emitting element 3 may further include an electron injection layer provided between the electron transport layer 35 and the cathode 36 and serving as a functional layer.

In addition, the display device 1 includes a bank BK on the substrate 2. The bank BK contains, for example, an insulative resin material including polyimide. With the bank BK, the anode 31 and the light-emitting layer 34 of the light-emitting element 3 are partitioned into the red subpixel SPR, the green subpixel SPG, and the blue subpixel SPB in a plan view of the substrate 2. In this embodiment, the light-emitting layer 34 in particular is partitioned with the bank BK into a red light-emitting layer 34R of the red subpixel SPR, a green light-emitting layer 34G of the green subpixel SPG, and a blue light-emitting layer 34B of the blue subpixel SPB. Whereas, although the anode 31 is partitioned for each of the subpixels as described above, the partitioned anodes 31 may have the same configuration regardless of the subpixels to be formed.

In this embodiment, the hole injection layer 32, the hole transport layer 33, the electron transport layer 35, and the cathode 36 are formed in common to the plurality of subpixels described above. Note that, the hole injection layer 32, the hole transport layer 33, the electron transport layer 35, and the cathode 36 may also be partitioned with the bank BK for each of the subpixels.

In this embodiment, the light-emitting element 3 includes: the red light-emitting element 3R positioned in the red subpixel SPR; the green light-emitting element 3G positioned in the green subpixel SPG; and the blue light-emitting element 3B positioned in the blue subpixel SPB. Hence, the red light-emitting element 3R, the green light-emitting element 3G, and the blue light-emitting element 3B are partially partitioned with the bank BK.

In particular, the red light-emitting element 3R includes: the anode 31; the hole injection layer 32; the hole transport layer 33; the red light-emitting layer 34R; the electron transport layer 35; and the cathode 36, all of which are formed at a position to overlap with the red subpixel SPR in a plan view of the substrate 2. The green light-emitting element 3G includes: the anode 31; the hole injection layer 32; the hole transport layer 33; the green light-emitting layer 34G; the electron transport layer 35; and the cathode 36, all of which are formed at a position to overlap with the green subpixel SPG in the plan view of the substrate 2. The blue light-emitting element 3B includes: the anode 31; the hole injection layer 32; the hole transport layer 33; the blue light-emitting layer 34B; the electron transport layer 35; and the cathode 36, all of which are formed at a position to overlap with the blue subpixel SPB in the plan view of the substrate 2.

Note that the bank BK may be formed at a position to cover an end portion of each anode 31. In other words, the bank BK may have an opening at a portion overlapping with the anode 31 in a plan view of the substrate 2. In this case, the bank BK can reduce an influence, of an electric field concentrated at the end portion of the anode 31 in each light-emitting element, on injection of holes from the anode 31 into the light-emitting layer 34.

### Light-Emitting Element: Anode and Cathode

At least one of the anode 31 or the cathode 36 is a transparent electrode that transmits visible light. The transparent electrode may be formed of such an oxide conductor as, for example, ITO, InZnO, SnO₂, or FTO. Alternatively, the transparent electrode may be formed of, for example, a non-light-transparent thin metal film containing such a metal as Mg or Ag, or an alloy of these metals. Furthermore, one of the anode 31 or the cathode 36 may be a reflective electrode. The reflective electrode may contain a metal material highly reflective to visible light. The metal material may be either a single-component metal such as, for example, Al, Ag, Cu, or Au, or an alloy of these metals.

In this embodiment, the anode 31 is a reflective electrode, and the cathode 36 is a transparent electrode. In this case, the display device 1 releases light of the light-emitting element 3 across from the substrate 2. That is, the display device 1 is a top-emission display device.

For example, as described above, the anode 31 is partitioned with the bank BK for each of the subpixels. Furthermore, each anode 31 is electrically connected to a corresponding pixel circuit. Whereas, the cathode 36 is formed in common to the plurality of subpixels, and receives a substantially constant voltage. Hence, the display device 1 causes a driver to control a voltage to be applied to each of the anodes 31 through the respective pixel circuits, thereby individually driving each of the light-emitting elements. When the anode 31 is driven in each light-emitting element, holes are generated in the anode 31 and electrons are generated in the cathode 36.

Each of the anode 31 and the cathode 36 may be formed of the above materials and deposited in a form of a thin film by such a technique as sputtering or vapor deposition. In particular, the anode 31 may be formed to electrically connect to a pixel circuit of the substrate 2. Alternatively, the anode 31 may be patterned for each of the subpixels.

### Light-Emitting Element: Hole Injection Layer: Nanoparticles

The hole injection layer 32 is a layer to inject the holes, which are generated in the anode 31, toward the light-emitting layer 34. The hole injection layer 32 according to this embodiment contains at least one nanoparticle 4 serving as a hole transport material. The nanoparticle 4 contains nickel oxide (NiO), and further contains nitrate ions (NO₃). Note that, in the present disclosure, the chemical formulas are typical examples. Furthermore, in the present disclosure, a composition ratio described in each of the chemical formulas is not necessarily in stoichiometry in which the composition of an actual compound is the same as the chemical formula.

A more specific configuration of the nanoparticle 4 according to this embodiment will be described by an analysis using a Fourier transform infrared spectrophotometer (an FT-IR). The FT-IR is a spectrometer that emits infrared rays to a sample and measures a transmitted or reflected infrared ray so as to measure an infrared absorption spectrum of the sample. Typically, when an infrared ray is emitted to a substance, a wave number (a wavelength) of the infrared ray absorbed into the substance varies depending on a functional group or ions contained in the substance. Hence, when the infrared absorption spectrum is measured by the analysis using the FT-IR, and the wave number of an absorption peak included in the infrared spectrum is identified, the functional group or the ions contained in the sample can be identified, and, eventually, at least a portion of the composition of the sample can be identified.

When the nanoparticles 4 according to this embodiment serve as a sample, and the infrared absorption spectrum is obtained by infrared spectroscopy with the FT-IR, the obtained infrared absorption spectrum has an absorption peak at a wave number corresponding to the nitrate ions. For example, as a sample, the nanoparticles 4 according to this embodiment is analyzed using the FR-IR, and the absorption spectrum obtained by the analysis has an absorption peak around a wave number of 1400 cm⁻¹.

### Light-Emitting Element: Hole Injection Layer: Method for Synthesizing Nanoparticles

Described below will be a method for synthesizing the nanoparticles 4 according to this embodiment. In the method for synthesizing the nanoparticles 4, first, a precursor aqueous solution is prepared. For example, 0.05 mmol of nickel nitrate hexahydrate (Ni(NO₃)₂·6H₂O) and 20 mL of pure water are mixed together and stirred, so that the precursor aqueous solution is prepared.

Then, an alkali aqueous solution is added to the obtained precursor solution. For example, 10 mol/L of an aqueous sodium hydroxide is added to the precursor aqueous solution until the mixture has a pH of 9 to 11, for example, 10. As a result, a precipitate, for example, a green precipitate is obtained.

Then, the obtained precipitate is rinsed. For example, pure water is added to the precipitate, and the mixture is centrifuged. After that, the supernatant fluid is removed. This rinse step is repeated three times.

Then, the rinsed precipitate is dried. For example, the rinsed precipitate is dried at a temperature of 60 to 100° C., for example, 80° C. As a result, powder, for example, a green powder is obtained.

Next, the obtained powder is fired. For example, the obtained powder is fired at 250° C. to 300° C. for 2 to 6 hours, for example, at 270° C. for 2 hours. As a result, the nanoparticles 4 are obtained in a black powdery state. The hole injection layer according to this embodiment may be deposited by such a method as application of a solution containing the nanoparticles 4 obtained at the above synthesizing step.

In view of the step of synthesizing the nanoparticles 4, the nitrate ions contained in the nanoparticles 4 are generated presumably because of the nickel nitrate hexahydrate contained in the precursor aqueous solution. More specifically, the nitrate ions contained in the nanoparticles 4 are presumably a portion of a by-product obtained by a reaction of the nickel nitrate hexahydrate and the alkali aqueous solution.

### Light-Emitting Element: Hole Transport Layer and Electron Transport Layer

Returning to the description of the layers of the light-emitting element 3, the hole transport layer 33 is a layer for transporting the holes, which are injected from the anode 31 into the hole injection layer 32, toward the light-emitting layer 34. The hole transport layer 33 may be made of an organic or inorganic hole transport material capable of transporting the holes for injection-electroluminescence light-emitting elements in the related art. Examples of the hole transport material include poly[(9,9-dioctylfluorenyl-2,7-diyl)-co-(4,4′-(N-(4-sec-butylphenyl))diphenylamine)] (abbreviated as “TFB”), poly[N,N′-bis(4-butylphenyl)-N,N′-bis(phenyl)-benzidine] (abbreviated as “poly-TPD”), and polyvinyl carbazole (abbreviated as “PVK”). The hole transport material may contain one of the above materials alone, or two or more of the above materials as appropriate.

The electron transport layer 35 is a layer for transporting the electrons, which are generated in the cathode 36, to the light-emitting layer 34. The electron transport layer 35 may be made of an organic or inorganic material serving as an electron transport material capable of transporting the electrons for injection-electroluminescence light-emitting elements in the related art. The electron transport material may contain zinc oxide (ZnO) and magnesium zinc oxide (MgZnO). The electron transport material may contain one of the above materials alone, or two or more of the above materials as appropriate.

In forming each of the hole transport layer 33 and the electron transport layer 35, for example, a solution in which a material described above is dispersed may be applied by such a technique as spin coating. After that, the applied solution may be fired and the solvent may be evaporated so that the hole transport layer 33 and the electron transport layer 35 may be deposited.

### Light-Emitting Element: Light-Emitting Layer

The light-emitting layer 34 contains a light-emitting material. When the holes injected from the anode 31 and the electrons injected from the cathode 36 recombine together so that an exciton is generated, the light-emitting material is excited by the exciton and emits light. The light-emitting layer 34 contains, for example, a plurality of quantum dots 5 serving as a light-emitting material. Each of the quantum dots 5 in the light-emitting layer 34 may have a core-shell structure including: a core that emits light with the exciton described above; and a shell formed around, and protecting, the core. Furthermore, in this embodiment, the light-emitting layer 34 may contain organic or inorganic ligands that form coordination bonds to an outer most peripheral surface of each of the quantum dots 5 in order to coordinate to the quantum dot 5.

Note that, in the present disclosure, the “quantum dots” are dots each having a maximum width of 100 nm or less. The quantum dot 5 may have any given shape as long as the maximum width of the quantum dot 5 is within the above range. The shape of the quantum dot 5 shall not be limited to a spherical shape (a circular cross-section). The quantum dot 5 may have, for example, a polygonal cross-section, a bar-like three dimensional shape, a branch-like three dimensional shape, or a three dimensional shape having asperities on the surface. Alternatively, the quantum dot 5 may have a combination of those shapes.

The quantum dots 5 may be typically made of a semiconductor. The semiconductor may have a certain bandgap. The semiconductor may be any given material capable of emitting light, and may include at least materials to be described below. The semiconductor may be capable of emitting a blue light, a green light, and a red light. The semiconductor includes at least one selected from the group consisting of, for example, a group II-VI compound, a group III-V compound, a chalcogenide, and a perovskite compound. Note that the group II-VI compound means a compound containing a group II element and a group VI element, and the group III-V compound means a compound containing a group III element and a group V element. Moreover, the group II element may include a group 2 element and a group 12 element, the group III element may include a group 3 element and a group 13 element, the group V element may include a group 5 element and a group 15 element, and the group VI element may include a group 6 element and a group 16 element.

The group II-VI compound includes at least one selected from the group consisting of, for example, MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe.

The group III-V compound includes at least one selected from the group consisting of, for example, GaAs, GaP, InN, InAs, InP, and InSb.

The chalcogenide is a compound containing a VI A (16) group element, and includes, for example, CdS or CdSe. The chalcogenide may contain a mixed crystal of these elements.

The perovskite compound has a composition represented by, for example, a general formula CsPbX₃. The constituent element X includes at least one selected from the group consisting of, for example, Cl, Br, and I.

Here, the group numbers of the elements in Roman numbers are denoted by the former International Union of Pure and Applied Chemistry (IUPAC) notation or by the former Chemical Abstracts Service (CAS) notation. The group numbers of the elements in Arabic numbers are denoted by the current IUPAC notation.

In this embodiment, the red light-emitting layer 34R includes red quantum dots 5R that emit a red light. The green light-emitting layer 34G includes green quantum dots 5G that emit a green light. The blue light-emitting layer 34B includes blue quantum dots 5B that emit a blue light. Each of a red quantum dot 5R, a green quantum dot 5G, and a blue quantum dot 5B may have the same configuration except for a color of the light to be emitted.

Hence, the display device 1 individually causes the red light-emitting element 3R, the green light-emitting element 3G, and the blue light-emitting element 3B to individually release the red light from the red subpixel SPR, the green light from the green subpixel SPG, and the blue light from the blue subpixel SPB. Hence, the display device 1 causes the display unit DA to display an image in full color.

Note that, in the present disclosure, the blue light has a center wavelength in a wavelength band of, for example, 380 nm or more and 500 nm or less. Furthermore, the green light has a center wavelength in a wavelength band of, for example, more than 500 nm and 600 nm or less. Moreover, the red light has a center wavelength in a wavelength band of more than 600 nm and 780 nm or less.

Note that the light-emitting layer 34 may have any given configuration as long as the light-emitting layer 34 contains a light-emitting material that emits light using the holes from the anode 31 and the electrons from the cathode 36. For example, the light-emitting layer 34 may contain an organic light-emitting material including either an organic fluorescent material or an organic phosphorescent material. In other words, the light-emitting element 3 may be an organic EL element (an OLED element), and the display device 1 may be an OLED display.

The light-emitting layer 34 may be formed for each of the subpixels by patterning using a lift-off technique. For example, first, a photosensitive resin is deposited in common to a plurality of subpixels, and a layer of the photosensitive resin is formed by such a technique as photolithography only for subpixels different from subpixels forming the light-emitting layer 34. Next, a solution in which the quantum dots 5 that emit light in any given color are dispersed is deposited in common to the plurality of subpixels. Then, the photosensitive resin is removed with an appropriate developing solution. Hence, the layer of the photosensitive resin is removed together with a layer formed on the layer of the photosensitive resin and containing the quantum dots 5. Hence, a layer containing specific quantum dots 5 can be formed only for a specific subpixel. The lift-off technique is repeatedly carried out for each of the subpixels so that the light-emitting layer 34 is formed. Note that the method for forming the light-emitting layer 34 shall not be limited to the above method. For example, an inkjet printing may be used to separately apply a solution in which the quantum dots 5 are dispersed, in order to form the light-emitting layer 34.

### Display Device: Additional Remarks

The light-emitting element 3 according to this embodiment can be produced to include: the anode 31, the hole injection layer 32 containing the nanoparticles 4; the hole transport layer 33; the light-emitting layer 34; the electron transport layer 35; and the cathode 36, all of which are formed on top of another in the stated order above the substrate 4. The layers of the light-emitting element 3 may be formed by the methods described above.

Note that this embodiment describes a case where each of the red light-emitting element 3R, the green light-emitting element 3G, and the blue light-emitting element 3B has the same multilayer structure except for the light-emitting layer 34. However, this embodiment shall not be limited to such a case. In this embodiment, at least one of the red light-emitting element 3R, the green light-emitting element 3G, or the blue light-emitting element 3B has the hole injection layer 32 containing the nanoparticles 4. In other words, the red light-emitting element 3R, the green light-emitting element 3G, and the blue light-emitting element 3B may have different multilayer structures.

The display device 1 may include, above the light-emitting element 3, either: an organic or inorganic sealing layer to seal the light-emitting element 3; or a capping layer to improve efficiency in releasing light from the light-emitting element 3. Alternatively, the display device 1 may include, above the light-emitting element 3, a touch panel unit for allowing the display device 1 to function as a touch panel display.

### Evaluation of Physical Properties: Synthesizing Nanoparticles

In order to evaluate physical properties of the nanoparticles 4 according to this embodiment, nanoparticles according to examples 1 to 6 and nanoparticles according to a comparative example were synthesized as described below. Furthermore, light-emitting devices were produced to each include a hole injection layer containing nanoparticles according to one of the examples and the comparative example. As will be described below, characteristics of the nanoparticles were evaluated.

The nanoparticles according to each of the examples 1 to 6 were synthesized in accordance with the method for synthesizing the nanoparticles 4 as described above. As to steps of synthesizing the nanoparticles according to the examples 1 to 6, the nanoparticles to be synthesized are different in total weight, and the same in ratio of the materials, between the examples. In particular, as to the steps of synthesizing the nanoparticles according to the examples 1 to 6, the precursor aqueous solutions to be prepared first are different only in weight between the examples, and substantially the same in proportion of the materials in the precursor aqueous solutions between the examples. The nanoparticles according to the comparative example are nanoparticles synthesized by a method different from the method for synthesizing the nanoparticles 4 as described above. In particular, the nanoparticles are synthesized by a method using not nickel nitride as a material but nickel oxide.

Evaluation of Physical Properties: Analyzing Nanoparticles using FT-IR and TG-DTA

Physical properties of the nanoparticles according to the examples and the comparative example were measured by a method below.

First, using an FT-IR, infrared spectroscopy was performed on the nanoparticles according to the examples and the comparative example, and an infrared absorption spectrum was obtained for the nanoparticles of each of the examples and the comparative example.

Next, using a thermogravimetry differential thermal analyzer (TG-DTA), the nanoparticles according to the examples and the comparative example were analyzed. Described below will be the analysis using the TG-DAT.

The TG-DTA includes: a furnace for heating a sample; and a measurement device for measuring a weight of the sample. Here, for example, in the analysis using the TG-DTA, an ambient temperature of the sample is raised at a predetermined temperature increasing rate using the TG-DTA to heat the sample, and variations in the weight of the sample are measured.

When the sample is heated, a portion of the sample is desorbed, dissolved, or reduced so that the sample might lose weight. Typically, an ambient temperature at which a material is desorbed, decomposed, or reduced upon heating of the sample depends on a kind of the material to be desorbed, decomposed, or reduced, and is substantially constant.

Hence, when analysis using the TG-DTA is carried out to measure the ambient temperature at which the sample loses weight, the material contained in the sample can be identified. Furthermore, when the analysis using the TG-DTA is carried out to measure the weight of the sample lost within a range of a predetermined ambient temperature, a proportion of a specific material in the sample can be estimated.

In analyzing the nanoparticles according to the examples and the comparative example, using the TG-DTA, the nanoparticles were heated by raising the ambient temperature from room temperature by 10° C. per minute. Here, in the analysis using the TG-DTA, the ambient temperature at which nitrate ions are desorbed, decomposed, or reduced from a sample containing the nitrate ions is typically 309° C. to 411° C. Hence, if nanoparticles to be heated in the analysis using the TG-DTA lose weight while the ambient temperature of the nanoparticles is between 309° C. and 411° C., the nanoparticles presumably contain nitrate ions. Furthermore, with reference to a weight of nanoparticles at room temperature, a percentage of the lost weight of the nanoparticles is measured while the ambient temperature is between 309° C. and 411° C., so that a proportion of the nitrate ions contained in the nanoparticles can be estimated.

### Evaluation of Physical Properties: Evaluating Dispersibility of Nanoparticles

Next, dispersibility of the nanoparticles according to the examples and the comparative example were evaluated. As to the evaluation of the dispersibility, first, for each of the examples and the comparative example, 30 mg of nanoparticles were added to 1 ml of pure water. Thus, an aqueous solution was prepared. Then, the aqueous solution was irradiated with ultrasonic waves at 45 kHz for 30 minutes.

Then, whether the nanoparticles of each of the examples and the comparative example were filtered was measured under a condition below, and the dispersibility of the nanoparticles was evaluated.

Ten micro liters of the aqueous solution prepared in each of the examples and the comparative example was collected, and 4 mL of pure water was added to the aqueous solution. The aqueous solution was subjected to measurement of an absorption spectrum, using a spectrophotometer (manufactured by Hitachi High-Tech Corporation, Model: U-3900). In particular, in this measurement, absorbance was measured for ultraviolet light having a wavelength of 250 nm.

Next, the remaining aqueous solution was filtered using a filter having a pore size of 0.45 μm, and 10 μL of the filtrate was collected. Then, 4 mL of pure water was added to the filtrate, and an absorption spectrum of the solution was measured. In this measurement, absorbance was measured for ultraviolet light having a wavelength of 250 nm.

A₁ represents the absorbance measured, in each of the examples and the comparative example, for the ultraviolet light having a wavelength of 250 nm observed before the aqueous solution is filtered. A₂ represents the absorbance measured, in each of the examples and the comparative example, for the ultraviolet light having a wavelength of 250 nm observed after the aqueous solution is filtered. Furthermore, R_{F} represents filtration permeability that is permeability of the nanoparticles of each of the examples and the comparative example through the above filter. In this embodiment, the filtration permeability R_{F} was evaluated in accordance with an equation below.

$${R}_{F} = A 2 \div A 1 \times 10 \; 0 .$$

Typically, if dispersibility of nanoparticles in water is low, the nanoparticles might agglomerate together in the aqueous solution. When a plurality of nanoparticles aggregates together to form a group, the group has a total particle size larger than a particle size of a single nanoparticle. Hence, by observing whether the nanoparticles in the aqueous solution pass through the filter having a predetermined pore size, the dispersibility of the nanoparticles in water can be evaluated. In particular, if the nanoparticles in the aqueous solution pass through the filter, the nanoparticles are evaluated to have high dispersibility in the aqueous solution.

In this embodiment, the particle size distribution (a median diameter of D50 (nm)) was measured with a nanoparticle size measuring apparatus (Model Number: “Nanotrac Wave II-UT151”) manufactured by MicrotracBell Inc. A result of the measurement of the particle size distribution was analyzed by a frequency analysis, using the dynamic light scattering (DLS). The particle size distribution (a median diameter of D50 (nm)) was measured by heterodyning.

Then, the nanoparticles passing the filter were added to pure water, and the resulting aqueous solution was subjected to measurement of the particle size distribution using a particle size distribution measurement apparatus. As to the measurement of the particle size distribution, the nanoparticles of each of the samples were measured to have a median diameter of D50 (nm). For the same reason as described above, the dispersibility of the nanoparticles in water can be evaluated through the measurement of the particle size distribution of the nanoparticles in the aqueous solution. In particular, if the nanoparticles per se are substantially the same in particle size, the nanoparticles can be evaluated to have higher dispersibility in the aqueous solution as the median diameter of the nanoparticles in the aqueous solution is smaller.

Note that, as will be described later, the nanoparticles according to the comparative examples did not pass through the filter, and thus, the subsequent evaluations were not carried out, including the measurement of the particle size distribution.

### Evaluation of Physical Properties: Evaluating External Quantum Efficiency of Light-Emitting Element

Next, using the nanoparticles according to each of the examples and subjected to the measurement of the particle size distribution, a light-emitting element was produced according to each of the examples. As to the light-emitting element according to each example, an anode, a hole injection layer containing the nanoparticles according to the example, a hole transport layer; a light-emitting layer, an electron transport layer, and a cathode were formed in the stated order above a substrate. Hence, the light-emitting element was produced. In particular, in each example, methods for forming the layers of the light-emitting element were the same as the methods for forming the layers of the light-emitting element 3 according to this embodiment, except that a material to be used for the hole injection layer was a solution containing the nanoparticles according to the example. Then, external quantum efficiency (EQE) of the light-emitting element produced according to each of the examples was measured and evaluated under a condition below.

In each example, as shown with the equations below, the external quantum efficiency (N_{φ(exe)}) was evaluated as the number of photons (Np) extracted per unit area of a cell prepared as the light-emitting element for evaluation with respect to the number of carriers (Ne) injected into the cell.

$$Np = λ / hc \times P \times 1 / S ( 1 / {m}^{2} ) ,$$

$$Ne = I / e \times 1 / S ( 1 / {m}^{2} ) , and$$

$${N}_{ϕ ( exe )} = Np / Ne \times 100 = ( P \times λ \times e ) / ( h c \times I ) \times 1 \; 00 ( \% ) .$$

Wherein, I represents a current (A), P represents light intensity (a measured light amount (W)), S represents an area of a cell (an element area (m²)), λ represents a peak emission wavelength (m), e represents an elementary charge (A·s), h represents a Planck constant (J·s), and c represents a light speed (m·s⁻¹).

The current (I) was measured with a Model 2400 source meter manufactured by Keithley Instruments Co., Ltd. The light intensity (P) was measured with a light intensity meter (Model Number: BM-5A) manufactured by Topcon House Co. Ltd. The area of the cell was set to 4×10⁻⁶ (m²). The emission peak wavelength (λ) was set to 536 (nm). The Planck constant was set to 6.626×10⁻³⁴ J·s. The element6ary charge (e) was set to 1.602×10⁻¹⁹ A·s. The light speed (c) was set to 2.998×10⁸ (m·s⁻¹).

### Evaluation of Physical Properties: Results of Evaluation

The evaluations of the physical properties are summarized in Table 1 below.

TABLE 1

| | | | | Particle Size | |
|---|---|---|---|---|---|
| | FT-IR/NO₃⁻ | TG-DTA/ | | Distribution | External |
| | Present or | Weight Loss | Filter Passed | Measurement/ | Quantum |
| | Absent | Percentage | or Not Passed | D50 [nm] | Efficiency [%] |
| Example 1 | Present | 18.0% | Passed | 12.48 | 8.5% |
| Example 2 | Present | 12.2% | Passed | 11.12 | 10.5% |
| Example 3 | Present | 10.7% | Passed | 19.32 | 9.1% |
| Example 4 | Present | 8.5% | Passed | 29.49 | 8.9% |
| Example 5 | Present | 18.9% | Passed | 14.55 | 5.8% |
| Example 6 | Present | 7.9% | Partially Passed | 34.49 | 4.8% |
| Comparative Example | Absent | 0.5% | Not Passed | — | — |

In Table 1, a column “FT-IR/NO₃⁻ Present or Absent” shows the presence or absence of an absorption peak at a wave number corresponding to nitrate ions in an infrared absorption spectrum obtained by an analysis of the nanoparticles according to each of the examples and the comparative example, using the FT-IR. A column “TG-DTA/Weight Loss Percentage” shows a percentage of a weight loss of the nanoparticles while the ambient temperature was 309° C. to 411° C. in the analysis using the TG-DTA described above, with reference to a weight of the nanoparticles at room temperature. A column “Filter Passed or Not Passed” shows whether the nanoparticles according to each of the examples and the comparative example passed the filter. In this column, “Passed” shows a case where the filtration permeability R_{F} measured by the above equation was 80% or more, “Partially Passed” shows a case the filtration permeability R_{F} was less than 80% and 20% or more, and “Not Passed” shows a case where the filtration permeability R_{F} was less than 20%. A column “Particle Size Distribution Measurement/D50 [nm]” shows in mm a result of the measurement of a median diameter of D50 obtained in measuring the particle size distribution for the nanoparticle aqueous solution according to each of the examples. A column “External Quantum Efficiency [%]” shows in percentage a measurement result of the external quantum efficiency measured when a voltage was applied to the light-emitting element according to each of the examples to cause the light-emitting element to emit light.

As Table 1 shows, the infrared absorption spectrum, which is obtained by an analysis of the nanoparticles according to this embodiment, using the FT-IR, has an absorption peak at a wave number corresponding to nitrate ions. Whereas, the absorption peak was not observed in the infrared absorption spectrum obtained by the analysis of the nanoparticles according to the comparative example, using the FT-IR.

Moreover, in the analysis of the nanoparticles according to each of the examples, using the TG-DTA, a weight loss of the nanoparticles by 7.9% to 18.9% was observed with reference to a weight observed at room temperature while the ambient temperature was 309° C. to 411° C. Whereas, in the analysis of the nanoparticles according to the comparative example, using the TG-DTA, the weight loss of the nanoparticles was hardly observed while the ambient temperature was 309° C. to 411° C.

The above results show that the nanoparticles according to each of the examples contain nitrate ions, and the nanoparticles according to the comparative example contain almost no nitrate ions.

As seen in Table 1, 80% or more of the nanoparticles according to the example 1 to the example 5 passed the filter described above. Furthermore, 70% or more of the nanoparticles according to the example 6 passed the filter. Whereas, only less than 20% of the nanoparticles according to the comparative example passed the filter. This shows that the nanoparticles according to the comparative example exhibit low dispersibility in the aqueous solution, which causes the nanoparticles to agglomerate together.

The above results show that nanoparticles containing nitrate ions, such as the nanoparticles according to each of the examples, exhibit higher dispersibility in the aqueous solution than nanoparticles containing no nitrate ions, such as the nanoparticles according to the comparative example.

When a functional layer is deposited to include a hole injection layer formed of a solution containing nanoparticles having high dispersibility in the aqueous solution according to each of the examples, the nanoparticles are less likely to agglomerate together in the functional layer. Typically, in a functional layer containing nanoparticles serving as, for example, a charge transport material, agglomeration of the nanoparticles causes deterioration in characteristics of the functional layer. Hence, the nanoparticles according to each of the examples exhibiting high dispersibility and low agglomeration in the solution can improve characteristics of the functional layer containing the nanoparticles. As to a light-emitting element including a functional layer containing the nanoparticles according to each of the embodiments, the functional layer can improve in characteristics. Hence, the light-emitting element can have a longer life thanks to improvement in light emission efficiency or in reliability of the functional layer. A display device including the light-emitting element can achieve higher display quality or operate on less power.

As Table 1 shows, the nanoparticles according to each of the examples 1 to 5 had a median diameter of 11.12 nm to 29.49 nm, and 30 nm or less. Whereas, the nanoparticles according to the example 6 had a median diameter of 34.49 nm, which is greater than 30 nm. This shows that the dispersibility of the nanoparticles according to each of the examples 1 to 5 in the aqueous solution is higher than the dispersibility of the nanoparticles according to the example 6 in the aqueous solution.

From the above results, when the nanoparticles 4 as a sample are analyzed by the above technique using the TG-DTA, the nanoparticles 4 may lose weight by 8.0% or more with reference to a weight at room temperature while the ambient temperature is 309° C. to 411° C. Furthermore, the nanoparticles 4 in the aqueous solution may have a median diameter of 30 nm or less. In this case, the nanoparticles 4 exhibit improvement in dispersibility in the aqueous solution.

As Table 1 shows, the light-emitting elements each having a hole injection layer containing the nanoparticles according to one of the examples 1 to 4 have external quantum efficiencies of 8.5% to 10.5%; that is, 8.0% or more. Whereas, the light-emitting elements each having a hole injection layer containing the nanoparticles according to one of the example 5 and 6 have external quantum efficiencies of 5.8% and 4.8%; that is, below 6.0%.

As can be seen, the external quantum efficiencies of the light-emitting elements according to the examples 1 to 4 are higher than the external quantum efficiency of the light-emitting element according to the example 5. This is probably because of a low proportion of nitrate ions contained in the nanoparticles in the hole injection layer of the light-emitting element according to each of the examples 1 to 4. Such nitrate ions are less likely to block transportation of the holes from the anode to the light-emitting layer.

Whereas, the external quantum efficiencies of the light-emitting elements according to the examples 1 to 4 are higher than the external quantum efficiency of the light-emitting element according to the example 6. This is probably because the nitrate ions contained in the nanoparticles according to each of the examples 1 to 4 increase the dispersibility of the nanoparticles in the aqueous solution, keep the nanoparticles from agglomerating together also in the hole injection layer, and improve the capability of the hole injection layer to transport the holes.

From the above results, when the nanoparticles 4 as a sample are analyzed by the above technique using the TG-DTA, the nanoparticles 4 may lose weight by 8.0% or more and 18.0% or less with reference to a weight at room temperature while the ambient temperature is 309° C. to 411° C. Such a feature can improve the external quantum efficiency of the light-emitting element 3 in which the hole injection layer 32 contains the nanoparticles 4.

### Appendices

The light-emitting element 3 according to this embodiment includes the nanoparticles 4 containing nickel oxide and serving as a material of the hole injection layer 32. Hence, as to the light-emitting element 3, the nitrate ions contained in the nanoparticles 4 keep the nanoparticles 4 from agglomerating together in the hole injection layer 32, and the nickel oxide contained in the nanoparticles 4 increases efficiency in injecting the holes into the light-emitting layer 34.

However, the light-emitting element 3 according to this embodiment shall not be limited to a configuration in which the nanoparticles 4 are contained as a material of the hole injection layer 32. For example, the nanoparticles 4 may be used for at least one of functional layers of the light-emitting element 3; that is, the hole transport layer 33, the light-emitting layer 34, and the electron transport layer 35. In this case, the nanoparticles 4 are less likely to aggregate together in the functional layers, and the characteristics of the functional layer can be improved.

In this embodiment, the light-emitting layer 34 contains the quantum dots 5 as a light-emitting material. Typically, as to a light-emitting element in which quantum dots are used as a light-emitting material of a light-emitting layer, the light-emitting layer tends to have holes in low concentration and electrons in excess amount. The excess electrons in the light-emitting layer not only decrease the light emission efficiency of the light-emitting element but also increase the risk of generating Auger electrons in the light-emitting layer, which might decrease reliability of the light-emitting element.

Hence, the light-emitting element 3 according to this embodiment, in which the quantum dots 5 are used as a light-emitting material of the light-emitting layer 34, includes the hole injection layer 32 containing the nanoparticles 4. Hence, the light-emitting element 3 reduces more efficiently the risk of excess electrons in the light-emitting layer 34. Thanks to such a feature, the nanoparticle 4 according to this embodiment can improve more efficiently the light emission efficiency and the reliability of the light-emitting light-emitting element 3. Note that, when the light-emitting layer of the light-emitting element contains a light-emitting material different from the quantum dots 5 such as, for example, an organic fluorescent material or an organic phosphorescent material, the nanoparticles 4 according to this embodiment may be used as a material of a functional layer included in the light-emitting element.

The present disclosure shall not be limited to the embodiment described above, and can be modified in various manners within the scope of claims. Different technical aspects disclosed in the embodiment are to be appropriately combined together to implement another embodiment. Such an embodiment shall be included within the technical scope of the present disclosure. Moreover, the technical aspects disclosed in the embodiment may be combined together to achieve a new technical feature.

1-9. (canceled)

10. Nanoparticles to be used for a functional layer of a light-emitting element, the nanoparticles comprising
nickel oxide, the nanoparticles having an infrared absorption spectrum obtained by infrared spectroscopy, and the infrared absorption spectrum having an absorption peak at a wave number corresponding to nitrate ions,
wherein, when the nanoparticles are heated by raising an ambient temperature from room temperature by 10° C. per minute, the nanoparticles lose weight by 8.0% or more and 18.0% or less with reference to a weight at the room temperature while the ambient temperature is 309° C. to 411° C.

11. The nanoparticles according to claim 10,
wherein, when 30 mg of the nanoparticles are added to 1 ml of pure water and an aqueous solution is synthesized, and the aqueous solution is irradiated with ultrasonic waves at 45 kHz for 30 minutes, 80% or more of the nanoparticles pass the filter.

12. The nanoparticles according to claim 11,
wherein the nanoparticles passing the filter are added to pure water so that an aqueous solution is prepared, and the aqueous solution is subjected to measurement of particle size distribution such that the nanoparticles have a median diameter of 30 nm or less.

13. A light-emitting element, comprising:
an anode; a cathode; and functional layers positioned between the anode and the cathode and including at least a light-emitting layer,
wherein at least one of the functional layers contains: nickel oxide;
nanoparticles having an infrared absorption spectrum obtained by infrared spectroscopy, the infrared absorption spectrum having an absorption peak at a wave number corresponding to nitrate ions; and
when the nanoparticles are heated by raising an ambient temperature from room temperature by 10° C. per minute, the nanoparticles lose weight by 8.0% or more and 18.0% or less with reference to a weight at the room temperature while the ambient temperature is 309° C. to 411° C.

14. The light-emitting element according to claim 13,
wherein the at least one functional layer containing the nanoparticles includes a hole injection layer positioned between the anode and the light-emitting layer.

15. The light-emitting element according to claim 13,
wherein the light-emitting layer contains a plurality of quantum dots serving as a light-emitting material.

16. A display device, comprising:
a substrate; and
a red light-emitting element, a green light-emitting element, and a blue light-emitting element, all of which are provided on the substrate,
wherein at least one of the red light-emitting element, the green light-emitting element, or the blue light-emitting element is the light-emitting element according to claim 13.

17. Nanoparticles to be used for a functional layer of a light-emitting element, the nanoparticles comprising
nickel oxide, the nanoparticles having an infrared absorption spectrum obtained by infrared spectroscopy, and the infrared absorption spectrum having an absorption peak at a wave number corresponding to nitrate ions,
wherein, when 30 mg of the nanoparticles are added to 1 ml of pure water and an aqueous solution is synthesized, and the aqueous solution is irradiated with ultrasonic waves at 45 kHz for 30 minutes, 80% or more of the nanoparticles pass the filter.

18. The nanoparticles according to claim 17,
wherein the nanoparticles passing the filter are added to pure water so that an aqueous solution is prepared, and the aqueous solution is subjected to measurement of particle size distribution such that the nanoparticles have a median diameter of 30 nm or less.
